(19) United States
(12) Patent Application Publication
(10) Pub. No.: US 2011/0062960 A1
(43) Pub. Date: Mar. 17, 2011

(54) DEVICE AND METHOD TO MONITOR ELECTRICAL CONTACT STATUS

(76) Inventors: Lenin Prakash, Bangalore (IN); John Dougherty, Collegeville, PA (US); Srinivasan Jeganathan, Bangalore (IN); Sirosh Sivasankaran, Bangalore (IN); G. Kalyana Sundaram, Bangalore (IN)

(21) Appl. No.: 12/559,553

(22) Filed: Sep. 15, 2009

(51) Int. Cl. G01R 31/327

(52) U.S. Cl. 324/423

(57) ABSTRACT

A method and apparatus for generating a status of an electrical contact pair in an electromagnetic switch by triggering an armature movement at a substantially consistent electrical phase angle, determining a magnetic lag angle between the electromagnetic switch closing and the electrical contact pair change of state, and generating a contact status using the magnetic lag angle is provided

### BACKGROUND OF THE INVENTION

1. Field of the Invention

The field of the present invention relates to electromechanical switches generally, and more particularly to a method for determining a status of the electrical contacts of an electromagnetic switch, as well as a device configured for use with such a method; of which the following is a specification, reference being had to the drawings accompanying and forming a part of the same.

2. Description of the Related Art

Electromagnetic switching devices such as contactors, relays, and other devices are well known and widely used to switch electrical currents. Conventional electromagnetic switches such as those having a moveable armature and a fixed yoke electromagnet as closing elements are commonly used to change the state of electrical contacts. When a current flows through the solenoid coils of the electromagnet, then the resultant magnetic field moves the armature toward the yoke, until the pole faces of the armature and yoke contact one another. When the current through the coils of the electromagnet is switched off, a mechanical resetting device such as a spring, for example, acts to separate the armature from the yoke. Movable electrical contact elements, which are connected to the armature, are moved with respect to stationary electrical contact elements in order to close and open the electrical contacts of the electromagnetic switching device. Such contacts may be of either normally closed or normally open configurations.

As shown in FIG. 1, a conventional electromagnetic switch 100 is shown, having an electromagnet 101 comprising a magnetic movable core or armature 102 separated by an air gap 104 from a magnetic stationary core or yoke 103 having an electromagnetic triggering solenoid or coil 105. The armature 102 is movable in the directions indicated by arrow 119. The movable armature 102 is in operable communication with at least one movable electrical contact 110a for making and breaking with a stationary electrical contact 110b. Although each pair of electrical contacts 110a, 110b are shown in FIG. 1 and described herein as in a normally open configuration, it will be understood by those of skill in the art that electrical contacts 110a, 110b may be of either normally closed or normally open configuration. Additionally, while FIG. 1 is shown having six pairs electrical contacts 110a, 110b it will be understood that movable armature 102 may be configured to be in operable communication with any number of electrical contacts. When closed, the contacts 110a, 110b typically conduct power from a power source 112, such as for example an AC power supply, to a load 115, and when the contacts 110a, 110b open, the power to the load 115 is interrupted.

When an electrical current (not shown) is passed through the triggering coil 105 of electromagnet 101, a magnetic field (not shown) is produced that causes the armature 102 to be magnetically attracted to the yoke 103. The movement of armature 120 causes at least one face 117 of armature 102 to make contact with at least one face 118 of yoke 103. The electrical current (not shown) through the triggering coil 105 is conventionally provided by a triggering circuit 120 or other external current source (not shown) connected to the triggering coil 105. Since the movable contact 110a is conventionally driven through a linking element 107 by the movable armature 102, the magnetic force developed by the electromagnet 101 holds the armature 102 in contact with the yoke 103 and thereby places the normally open electrical contacts 110a, 110b in an actuated or closed state. Then, when the electrical current (not shown) is cut off, the electromagnet 101 is de-energized, and a return element such as, for example, a spring 106 returns the armature 102 to its initial position thereby causing the at least one face 117 of armature 102 to break contact with the at least one face 118 of yoke 103, and the electrical contacts 110a, 110b to change state (i.e., open).

During each opening and closing operation of electrical contacts 110a, 110b when switching currents, electrical arcing occurs in an air gap between the contacts 110a, 110b. The electrical arcing results in material erosion of the switching contacts 110a, 110b that varies in severity depending at least on the current and voltage load. The material erosion or wear influences the switching behavior of the switching device, and after a sufficient number of switching operations, can cause a failure of the switching device. Additionally, arcing-induced erosion of electrical contacts 110a, 110b is a significant factor determining the remaining life of, or maintenance interval for, a switching device. It is important to know the contact status, such as for example, the remaining contact material thickness or remaining expected contact life, to enable preventive maintenance, such as replacing the contacts 110a, 110b or the electromagnetic switching device 100 itself, to avoid unplanned interruption to the system in which the switching device 100 is used.

One typical practice used to prevent such unplanned system interruption is to systematically replace either the contacts 110a, 110b or the electromagnetic switching device 100 itself, after a predetermined number of operations without examining the actual condition of the contacts 110a, 110b. This results in unnecessary replacement of devices if the contacts are not sufficiently worn, and may result in device and/or system failure if the electrical contacts 110a, 110b have worn more than anticipated.

Therefore, what is needed is a method to more precisely determine the status, such as the remaining thickness of the electrical contacts in order to deduce information related to the residual life of the contacts, since it would enable timely notification to the user, and thus prevent failures that could otherwise occur.

### BRIEF DESCRIPTION OF THE INVENTION

In view of the foregoing considerations, it is desirable to provide a device and method to generate the status of the electrical contacts in an electromagnetic switching device. The generated status may comprise any number of embodiments, including such non-limiting examples as an indication of the residual life of the electrical contacts; an indication of the current thickness of the electrical contacts; a pass/fail indication of the condition of the electrical contacts; or a notification regarding necessary maintenance of the electrical contacts.

As used herein, the instant of contact between armature and yoke shall be referred to as closing of the electromagnetic switch. Additionally, the term change of state in reference to a pair of electrical contacts shall refer herein to opening of closed contacts, or alternatively, closing of open contacts. The electrical phase angle difference between the closing of the electromagnetic switch, and the change of state of the electrical contacts is referred to herein as a magnetic lag angle (MLA).

FIG. 2 is a graph illustrating a typical MLA for a conventional electromagnetic switch wherein, for example, an AC voltage V_{c} is applied across normally open electrical contacts and a DC voltage signal Vₘ is applied across the electromagnetic armature and yoke to sense the close of the electromagnetic switch. When a triggering current through coil causes the electromagnetic switch to close, the point on the AC waveform, herein referred to as an electrical phase angle, of the voltage signal Vc at which the electrical contacts change state (e.g., close) thereby dropping Vc to zero, will typically lead the electrical phase angle at which the armature makes contact with the yoke (i.e., closes). The phase angle difference between the leading electrical phase angle at the electrical switch contacts change of state, and the lagging electrical phase angle at the closing of the electromagnetic switch is the MLA.

In accordance with an aspect of the invention, the problem of determining contact status is solved by triggering the armature movement at a substantially consistent electrical phase angle, determining the MLA between electromagnetic switch closing and the electrical contact change of state, and generating a contact status using the MLA.

In one embodiment, a MLA value corresponding to a known contact status is predetermined, a moving average of the measured MLA values is determined, and the moving average is compared with the predetermined MLA value to generate a contact status.

Other features and advantages of the disclosure will become apparent by reference to the following description taken in connection with the accompanying drawings.

The above brief summary sets forth rather broadly the more important features of the present invention in order that the detailed description thereof that follows may be better understood, and in order that the present contributions to the art may be better appreciated. In this respect, before explaining several embodiments of the invention in detail, it will be understood that the invention is not limited in its application to the details of the construction and to the arrangements of the components set forth in the following description or illustrated in the drawings. The invention is capable of other embodiments and of being practiced and carried out in various ways. Also, it is to be understood, that the phraseology and terminology employed herein are for the purpose of description and should not be regarded as limiting.

As such, those skilled in the art will appreciate that the conception, upon which disclosure is based, may readily be utilized as a basis for designing other structures, methods, and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings. Although specific features of the invention are shown in some drawings and not in others, this is for convenience only as one or more of the features of any drawing may be combined with any or all of the other features of one or more of the remaining drawings in accordance with one or more embodiments of the invention. The accompanying drawings, which are incorporated in and constitute a part of the specification, illustrate a presently preferred embodiment of the invention, in which:

FIG. 1 illustrates a conventional electromagnetic switching device of the kind known in the prior art;

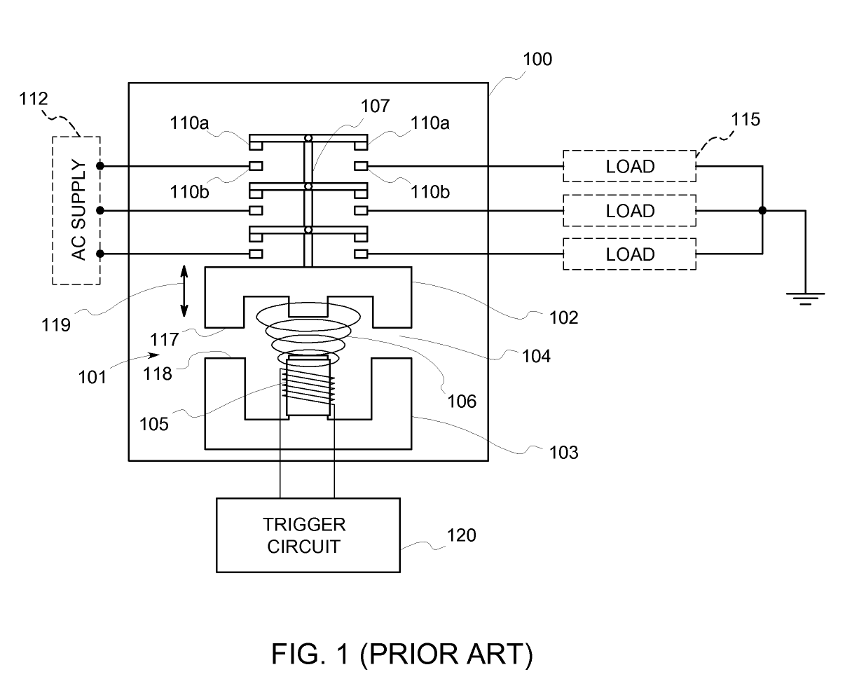

FIG. 2 is a graph illustrating voltage signals associated with an electromagnetic switching device;

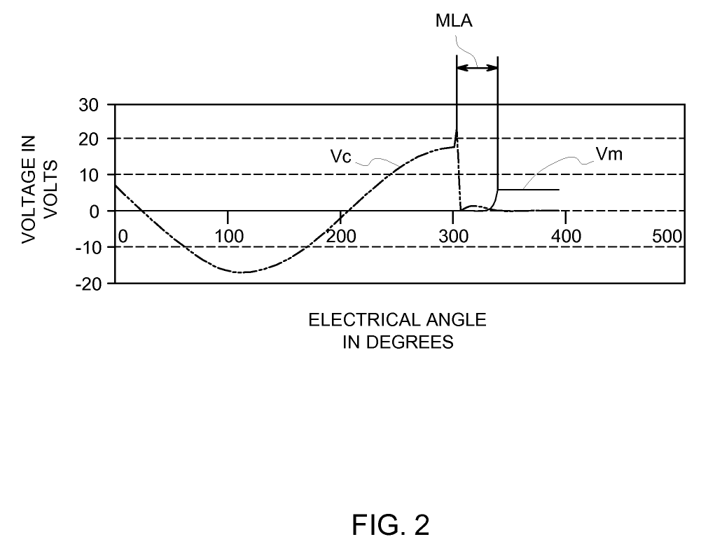

FIG. 3 illustrates a schematic view of an embodiment of the present invention;

FIG. 4 illustrates a schematic view of an alternative embodiment;

FIG. 5 is a flow diagram of a computer-implemented method according to an embodiment.

### DETAILED DESCRIPTION OF THE PREFERRED EMBODIMENTS

As used herein, an element or function recited in the singular and proceeded with the word “a” or “an” should be understood as not excluding plural said elements or functions, unless such exclusion is explicitly recited. Furthermore, references to “one embodiment” of the claimed invention should not be interpreted as excluding the existence of additional embodiments that also incorporate the recited features.

Referring now to the drawings, wherein like reference numerals designate identical or corresponding parts throughout the several views, one of the embodiments of the present invention will now be described.

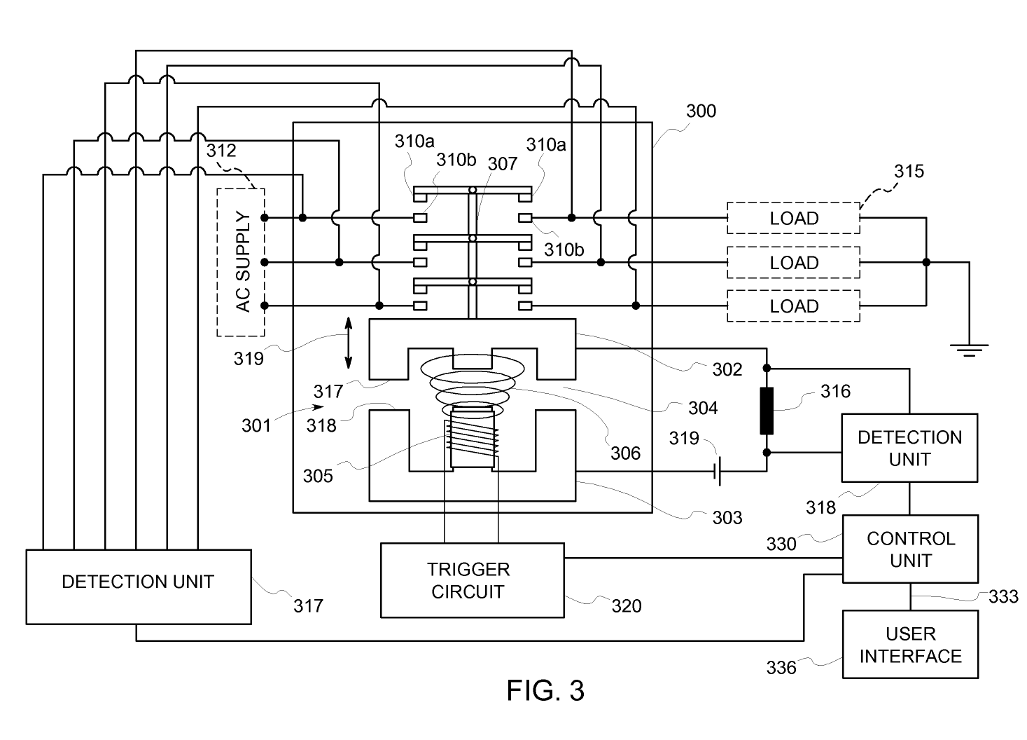

In FIG. 3 a schematic view of an electromagnetic switch 300 of an embodiment is shown, having an electromagnet 301 comprising a movable core or armature 302 separated by an air gap 304 from a stationary core or yoke 303 having an solenoid or triggering coil 305, and connected to a movable electrical contact 310a for making and breaking with a stationary electrical contact 310b. Although the contacts 310a, 310b are shown in the Figures and described herein as in a normally open configuration, it will be understood by those of skill in the art that the contacts 310a, 310b may be of either normally closed or normally open configuration. When closed, the contacts 310a, 310b typically conduct power from a power source 312, such as for example an AC power supply, to a load 315, and when the contacts 310a, 310b open, the power to the load 315 is interrupted. Electrical current (not shown) through the triggering coil 305 magnetically triggers movement of armature 302 toward yoke 303 and is provided by a triggering circuit 320 connected to the triggering coil 305. The movement of armature 320 causes at least one face 317 of armature 302 to contact at least one face 318 of yoke 303 (i.e., close the electromagnetic switch). The movable contact 310a is driven through a linking element 307 by the movable armature 302, and the magnetic force developed by the electromagnet 301 holds the movable and stationary contacts 310a, 310b in an actuated or closed position. When the electrical current (not shown) is cut off, the electromagnet 301 is de-energized, and a return element such as, for example, a spring 306 or gravity returns the armature 302 to its initial position causing the contacts 310a, 310b to change state or open.

Generally, after an initial break-in number of cycles, the MLA of an electromagnetic switching device will decrease over the life of the electrical contacts from an initial value to a minimum value before device failure. The decline or decay in the MLA has been seen to be generally a function of the erosion of the electrical contact material and other variable factors: (a) the remaining thickness of the contacts 310a, 310b; (b) the closing velocity and acceleration of moveable armature 302, and (c) general mechanical wear of the electromagnetic switching device 300 parts. By minimizing the effects of the other variable factors as discussed supra, for each electromagnetic switching device, a family of curves or table of values can be empirically developed that indicate the thickness of the switching device electrical contacts for a particular value or range of values of the MLA.

In the present invention, the change in the MLA value, over a plurality of energizing operations of the electromagnetic switch 300, due to the reduction in contact thickness caused by contact erosion is advantageously used to generate a status of electrical contacts 310a, 310b and hence the anticipated residual life of electromagnet switch 300. The generated status may comprise any number of embodiments, including such non-limiting examples as an indication of the residual life of the electrical contacts, such as the number of operations remaining; an indication of the current thickness of the electrical contacts; a pass/fail indication of the condition of the electrical contacts; or a notification regarding necessary maintenance of the electrical contacts. In order to use the MLA to provide an indication of electrical contact status, the effect of the aforementioned variable factors, other than the remaining contact 310a, 310b thickness, causing the change in MLA should be eliminated or greatly reduced.

In one embodiment, the influence over time of the aforementioned variable factor of general mechanical wear of the electromagnetic switch 300 parts on the measured values of MLA is diminished by determining the moving average of the measured values of MLA. The MLA moving average value is compared with a predetermined MLA value corresponding to a known contact status. By negating the effects on the measured values of MLA of general mechanical wear of the electromagnetic switch 300 parts, other than the electrical contacts 310a, 310b themselves, the rolling average value of MLA is used provide a more precise indication of the electrical contacts 310a, 310b status.

According to another aspect, a control unit 330 such as, for example a microcontroller or microprocessor, is in operable communication with the first and second detection circuits 317, 318 and the trigger circuit 320. Control unit 330 comprises an internal memory (not shown) configured to store data, such as for example, in a lookup table, related to a status of the switching device electrical contacts 310a, 310b for a particular value or range of values of the MLA. The control unit 330 also comprises a processing unit (not shown) configured determine the MLA using the electrical phase angle difference between the closing of the electromagnetic switch, and the change of state of the electrical contacts. The control unit 330 processing unit (not shown) is also configured determine to compare the determined MLA values with the stored lookup table values, in order to determine any number of aspects related to contact status, including such non-limiting examples as the expected residual life of the electrical contacts 310a, 310b, the number of electrical contact operations completed or remaining; the current thickness of the electrical contacts 310a, 310b; the general condition of the electrical contacts 310a, 310b; or necessary maintenance of the electrical contacts.

The velocity and acceleration of the armature 302 depends substantially upon the electrical closing angle at which the triggering coil 305 is energized. By consistently energizing the triggering coil 305 at substantially the same predetermined electrical angle through each operation of the device 300, the closing velocity and acceleration of the armature 302 is kept substantially constant. It will be understood that a variety of known triggering circuits 320 may be used to provide an energizing signal to the triggering coil 305. In a non-limiting example, an electronic switch such as, a triode for alternating current (TRIAC) may be connected in series with the electromagnetic triggering coil 305. The TRIAC can then be fired at a particular electrical phase angle, which is kept constant throughout the life of the switching device 300.

By maintaining the closing velocity and acceleration of armature 302 substantially constant through each operation, the MLA can be used to generate a more precise indication of the contact 310a, 310b status.

Referring still to FIG. 3, an embodiment is shown in which a phase controlled trigger circuit 320 energizes the electromagnetic triggering coil 305. The trigger circuit 320 is in communication with the control unit 330. A first detection circuit 317 is also in communication with the control unit 330 for detecting and providing an indication of switch closing between the contacts 310a, 310b. The closing angle of switch closing between the electrical contacts 310a, 310b is thereby measured and may be stored in the memory (not shown) of control unit 330.

In one embodiment, the first detection circuit 317 senses the instant of closing of contacts 310a, 310b by detecting the current flow across the contacts. Alternatively, in another embodiment, the first detection circuit 317 senses the instant of closing of contacts 310a, 310b by detecting the resulting change in voltage, or voltage drop, across the contacts 310a, 310b. It will be understood that the detection of the closing of electrical contacts 310a, 310b may be accomplished using a number current or voltage detection circuits known in the art.

A second detection circuit 318 is in signal communication with the control unit 330 for providing an indication of electromagnetic switch closing between the armature 302 and yoke 301. In one embodiment, the second detection circuit 318 senses the instant of closing of the moving armature 302 with the yoke 301 by detecting the appearance of a dc voltage (not shown) across a resistance 316 connected in series with a low voltage dc source 319 electrically connected in series with the armature 302 and yoke 301. The closing angle of the moving armature 302 and yoke 301 is thereby measured and may be stored in the memory (not shown) of control unit 330.

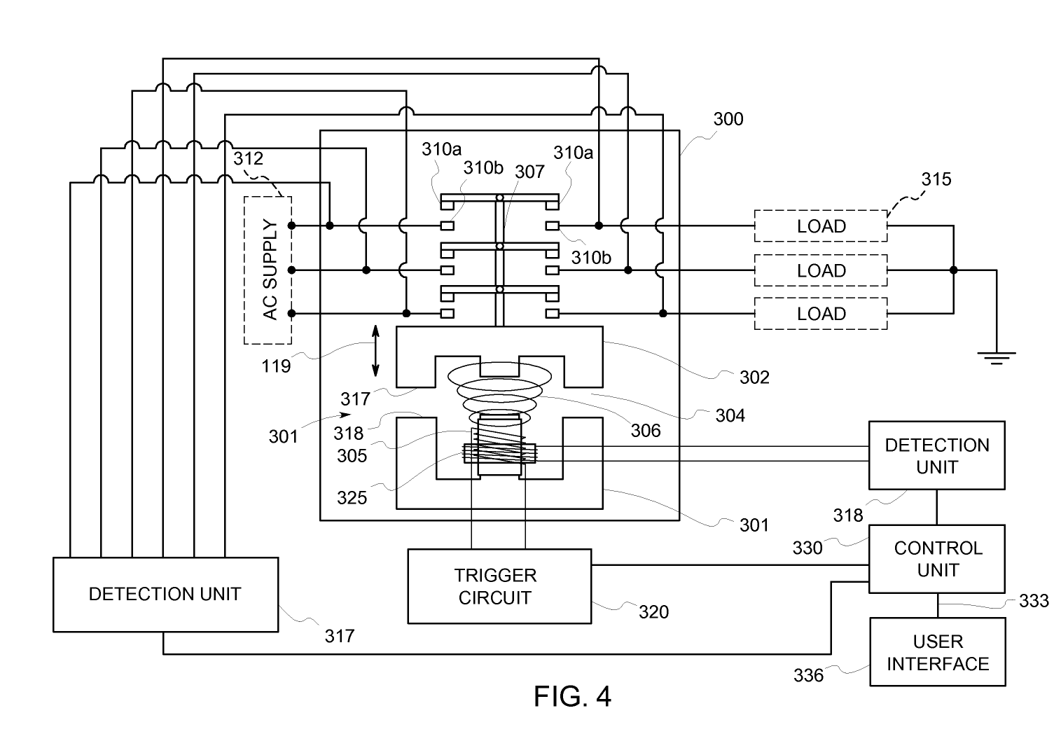

FIG. 4 illustrates an alternative embodiment wherein a detection coil 325 is wound over the triggering coil 305 and is in signal communication with second detection circuit 318. In this embodiment, at the instant of closing of the electromagnetic switch 300, an electromotive force (emf) is induced due to the high rate of change of flux, thus causing a rise in voltage in the detection coil 325. The second detection circuit 318 senses the instant of closing of the electromagnetic switch 300 by detecting the rise in voltage in the detection coil 325.

According to another aspect, the control unit 330 is in operable communication with a communication bus 333 such as for example a serial link, a field bus, a Local Area Network (LAN), or global network. The microcontroller 330 is connected to the communication bus 333 so that information related to the status of an electrical contacts 310a, 310b, stored in the microcontroller 330 internal memory (not shown) can be transmitted on the communication bus 333.

In another embodiment, the switching device comprises a user interface 336 preferably in operable communication with the control unit 330. The user interface 336, Non-limiting examples of User Interface 335 include a graphic display screen; an indicator light; an audible signal, and is used to provide or display information related to the status of electrical contacts 310a, 310b, stored in the control unit 330 internal memory (not shown).

While the various embodiments have been described generally with reference to single phase circuits, it will been seen that the embodiments are not so limited and are equally useful with other voltage configurations. For example, in the case of a three-phase circuit, the MLA is determined in each of the three phases. In one embodiment, the MLA values are determined separately for each phase and then are compared by the control unit 330 and the phase having the minimum value (i.e., indicative of the greatest erosion of the contacts 310a, 310b) is considered for the contact 310a, 310b status determination. Additionally, while the embodiments herein have been shown having six sets of contacts 310a, 310b, it will be understood that the embodiments are not so limited, and may be configured with a single pair of contact 310a, 310b, or any other convenient number of contact pairs 310a, 310b.

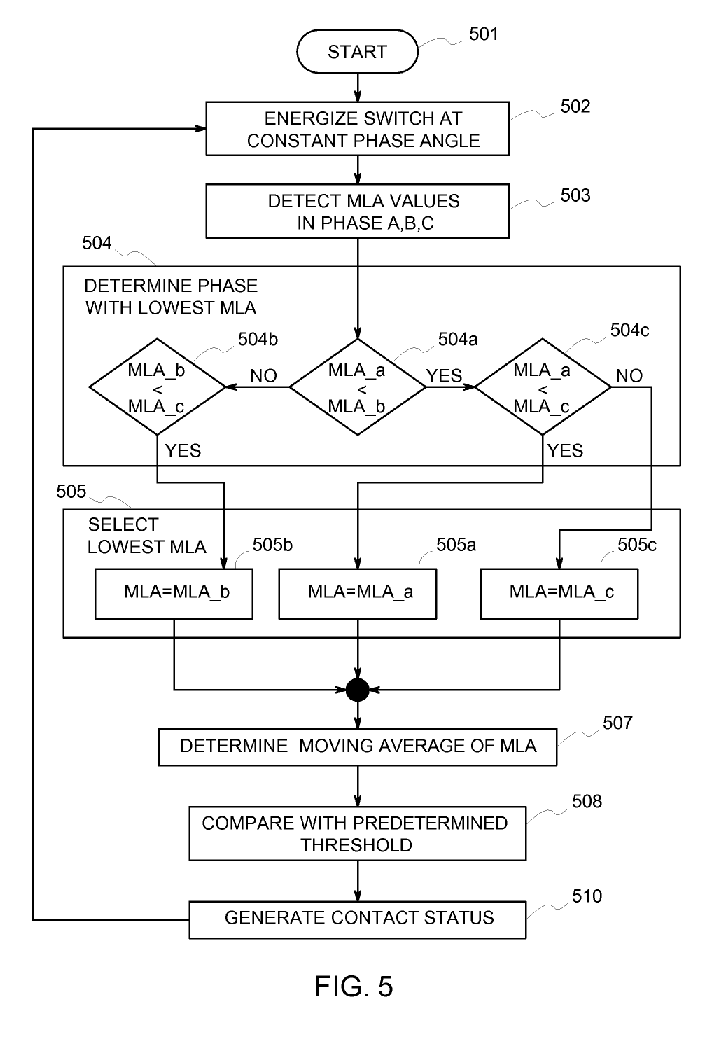

FIG. 5 is a flow diagram of a computer-implemented method according to an embodiment of the invention. Each block, or combination of blocks, depicted in the block diagram can be implemented by computer program instructions. These computer program instructions may be loaded onto, or otherwise executable by, a computer or other programmable apparatus to produce a machine, such that the instructions, which execute on the computer or other programmable apparatus create means or devices for implementing the functions specified in the block diagram. These computer program instructions may also be stored in a computer-readable memory that can direct a computer or other programmable apparatus to function in a particular manner, such that the instructions stored in the computer-readable memory produce an article of manufacture, including instruction means or devices which implement the functions specified in the block diagrams, flowcharts or control flow block(s) or step(s). The computer program instructions may also be loaded onto a computer or other programmable apparatus to cause a series of operational steps to be performed on the computer or other programmable apparatus to produce a computer implemented process such that the instructions which execute on the computer or other programmable apparatus provide steps for implementing the functions specified in the block diagrams, flowcharts or control flow block(s) or step(s).

Accordingly, blocks or steps of the flowchart illustration supports combinations of means or devices for performing the specified functions, combinations of steps for performing the specified functions and program instruction means or devices for performing the specified functions. It will also be understood that each block or step of the flowchart, and combinations of blocks or actions depicted in the flowchart, can be implemented by a special or general-purpose hardware-based computer system that is configured to perform the specified functions or steps, or combinations of special purpose hardware and computer instructions.

Referring now to FIG. 5, a flow chart illustrates an embodiment of the present invention for determining a status of an electrical contact of an electromagnetic switch having 3-poles, designated pole a, pole b, and pole c, respectively, in an electrical system having three-phases, designated phase A, phase B, and phase C, respectively. It will be understood that the process shown in FIG. 5 is not so limited, and may be also used to generate a status of an electrical contact of an electromagnetic switch in other types of electrical systems, such as a single-phase electrical system, and for other types of switches, such as a single-pole switch.

At step 502 the method begins by energizing the electromagnetic switch 300 at a substantially constant electrical phase angle. At step 503, the MLA values are determined for each electrical switch contact, pole a, pole b, and pole c, corresponding to each electrical system phase A, phase B, and phase C, respectively.

At step 504, each of the MLA values determined in step 503 are compared. For example, at 504a the MLA value for the electrical switch contact 310a, 310b of pole a is compared with the MLA value for the electrical switch contact 310a, 310b of pole b; at 504b the MLA value for the electrical switch contact 310a, 310b of pole b is compared with the MLA value for the electrical switch contact 310a, 310b of pole c; and at 504c the MLA value for the electrical switch contact 310a, 310b of pole a is compared with the MLA value for the electrical switch contact 310a, 310b of pole c.

At step 505, the lowest MLA value determined in step 504 is selected. At step 507, the MLA value selected in step 505 is used to determine the moving average of selected MLA values from previous switch 300 operations. At step 508, the moving average value determined in step 507 is compared with a predetermined threshold value. At step 510, the contact status of the device is generated based on the comparison of the MLA value determined in step 507 and the predetermined threshold value.

With respect to the above description, it should be realized that the optimum dimensional relationships for the parts of the invention, to include variations in size, form function and manner of operation, assembly and use, are deemed readily apparent and illustrated in the drawings and described in the specification are intended to be encompassed only by the scope of appended claims.

In addition, while the present invention has been shown in the drawings and fully described above with particularity and detail in connection with what is presently deemed to be practical and several of the preferred embodiments of the invention, it will be apparent to those of ordinary skill in the art that many modifications thereof may be made without departing from the principles and concepts set forth herein. Hence, the proper scope of the present invention should be determined only by the broadest interpretation of the appended claims so as to encompass all such modifications and equivalents.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope claims, or if they include equivalent structural elements with insubstantial differences from the literal languages of the claims.

What is claimed is:

1. A method for generating a status of an electrical contact pair of an electromagnetic switch having a movable armature and a fixed yoke, wherein the electrical contact pair is coupled with the movable armature, the method comprising:
a) triggering the electromagnetic switch at a first substantially constant electrical phase angle;
b) measuring a second electrical phase angle at a change of state of the electrical contact pair;
c) measuring a third electrical phase angle at the closing of the electromagnetic switch;
d) determining a magnetic lag angle as a difference between said second phase angle and said third phase angle; and
e) generating a status of the contact pair using said magnetic lag angle.

2. The method of claim 1, wherein said measuring a second electrical phase angle at a change of state of the electrical contact pair comprises sensing a change in electrical field intensity across the contact pair.

3. The method of claim 1 wherein said measuring a second electrical phase angle at a change of state of the electrical contact pair comprises sensing a conducting or a non-conducting state of the electrical contact pair.

4. The method of claim 1 wherein said measuring a third electrical phase angle at the closing of the electromagnetic switch comprises sensing an electrical make or break of the armature and the yoke.

5. The method of claim 1 wherein said generating a status of the contact pair comprises providing an indication of remaining contact life.

6. A method for generating a status of an electrical contact pair of an electromagnetic switch having a movable armature and a fixed yoke, wherein the electrical contact pair is configured to be coupled with the movable armature, the method comprising:
a) triggering the electromagnetic switch at a first substantially constant electrical phase angle;
b) measuring a second electrical phase angle at a change of state of the electrical contact pair;
c) measuring a third electrical phase angle at the closing of the electromagnetic switch;
d) determining a magnetic lag angle as a difference between said second phase angle and said third phase angle;
e) determining a moving average value of said magnetic lag angle; and
f) generating a status of the electrical contact pair using said moving average value.

7. The method of claim 6, wherein said determining a second electrical phase angle at a change of state of the electrical contact pair comprises sensing a change in electrical field intensity across the contact pair.

8. The method of claim 6 wherein said measuring a second electrical phase angle at a change of state of the electrical contact pair comprises sensing a conducting or a non-conducting state of the electrical contact pair.

9. The method of claim 6 wherein said measuring a third electrical phase angle at the closing of the electromagnetic switch comprises magnetically sensing an electrical make or break of the armature and the yoke.

10. The method of claim 6 further comprising providing an indication of a status of the electrical contact pair

11. An apparatus for use with an electromagnetic switch having a movable armature and a fixed yoke, wherein an electrical contact pair is coupled with the movable armature, said apparatus comprising:
a) a control unit;
b) a trigger circuit in communication with said control unit, said trigger circuit configured to actuate the electromagnetic switch at a substantially consistent first electrical phase angle;
c) a first detection unit configured to detect a change of state of the electrical contact pair;
d) a second detection unit configured to detect a close of the electromagnetic switch;
e) said first and second detection units in communication with said control unit;
f) said control unit being configured to
1. measure a second electrical phase angle at the change of state of the electrical contact pair;
2. measure a third electrical phase angle at the closing of the electromagnetic switch;
3. determine a magnetic lag angle as a difference between said second phase angle and said third phase angle; and
4. generate a status of the electrical contact pair as a function of said magnetic lag angle.

12. The apparatus of claim 11, wherein said change of state of the electrical contact pair comprises a change in electrical field intensity across the electrical contact pair.

13. The apparatus of claim 11 wherein said change of state of the electrical contact pair comprises a change in the conducting state of the electrical contact pair.

14. The apparatus of claim 11 wherein said closing of the electromagnetic switch comprises an electrical make or break of the armature and the yoke.

15. The apparatus of claim 11 wherein said control unit is further configured to provide an indication of remaining contact life.

16. An apparatus for use with an electromagnetic switch having a movable armature and a fixed yoke, wherein an electrical contact pair is coupled with the movable armature, said apparatus comprising:
a) a control unit;
b) a trigger circuit in communication with said control unit, said trigger circuit configured to electrically actuate the electromagnetic switch at a substantially consistent first electrical phase angle;
c) a first detection unit configured to detect a change of state of the electrical contact pair;
d) a second detection unit configured to detect a close of the electromagnetic switch;
e) said first and said second detection units being in communication with said control unit;
f) said control unit being configured to
1. measure a second electrical phase angle at the change of state of the electrical contact pair;
2. measure a third electrical phase angle at the closing of the electromagnetic switch;
3. determine a magnetic lag angle as a difference between said second phase angle and said third phase angle;
4. determine a moving average value of the magnetic lag angle over multiple switch operations; and
5. generate a status of the contact pair using said rolling average value.

17. The apparatus of claim 16, wherein said change of state of the electrical contact pair comprises a change in electrical field intensity across the electrical contact pair.

18. The apparatus of claim 16 wherein said change of state of the electrical contact pair comprises a change in the conducting state of the electrical contact pair.

19. The apparatus of claim 16 wherein said closing of the electromagnetic switch comprises an electrical make or break of the armature and the yoke.

20. The apparatus of claim 16 wherein said control unit is further configured to provide a status of the electrical contact pair.
